(19) United States
(12) Patent Application Publication
(10) Pub. No.: US 2025/0248241 A1
(43) Pub. Date: Jul. 31, 2025

(54) LIGHT EMITTING DEVICE, DISPLAY DEVICE, PHOTOELECTRIC CONVERSION DEVICE, ELECTRONIC APPARATUS, ILLUMINATION DEVICE, MOVING BODY, AND WEARABLE DEVICE

(71) Applicant: CANON KABUSHIKI KAISHA, Tokyo (JP)

(72) Inventors: SHUSUKE YANAGAWA, Kanagawa (JP); SHOJI KONO, Tokyo (JP); MASAAKI IWANE, Kanagawa (JP)

(21) Appl. No.: 19/023,965

(22) Filed: Jan. 16, 2025

(30) Foreign Application Priority Data
Jan. 31, 2024 (JP) 2024-013307

(51) Int. Cl. H10K 59/127; F21K 9/69; F21Y 115/15; H04N 23/63; H10K 59/131

(52) U.S. Cl. CPC H10K 59/1275; H10K 59/131; F21K 9/69; F21Y 2115/15; H04N 23/63

(57) ABSTRACT

A light emitting device in which a first substrate including a display region where a plurality of pixels are arranged and a second substrate including circuits configured to operate the plurality of pixels are stacked, is provided. The circuits include a first circuit and a second circuit located between the first circuit and an outer edge of the second substrate, and the first circuit has a larger heat generation amount per unit area than the second circuit. In an orthogonal projection to a main surface of the first substrate including the display region, the first circuit is arranged inside the outer edge of the display region, and a center of the display region is arranged inside an outer edge of the first circuit.

### BACKGROUND OF THE INVENTION

### Field of the Invention

The present invention relates to a light emitting device, a display device, a photoelectric conversion device, an electronic apparatus, an illumination device, a moving body, and a wearable device.

### Description of the Related Art

Japanese Patent Laid-Open No. 2023-044407 describes a display device in which a substrate where a display region including a plurality of light emitting elements is arranged and a substrate where a driving circuit is arranged are stacked. Since the light emission intensity of the light emitting element depends on temperature, Japanese Patent Laid-Open No. 2023-044407 describes that the power consumption of the driving circuit is reduced to suppress generation of a non-uniform temperature distribution in the display region caused by the heat generated by the driving circuit.

### SUMMARY OF THE INVENTION

In a display device, power for driving a display region can be supplied from the outside of the display region, so that a non-uniform light emission intensity distribution caused by the voltage drop of a power supply voltage may be generated from the outer periphery of the display region toward the center thereof. It is necessary to consider not only the light emission intensity distribution caused by the temperature distribution but also the light emission intensity distribution caused by the distribution of power supply voltage supplied to the display region.

Some embodiments of the present invention provide a technique advantageous in suppressing a non-uniform light emission intensity distribution.

According to some embodiments, a light emitting device in which a first substrate including a display region where a plurality of pixels are arranged and a second substrate including circuits configured to operate the plurality of pixels are stacked, wherein the circuits include a first circuit and a second circuit located between the first circuit and an outer edge of the second substrate, the first circuit has a larger heat generation amount per unit area than the second circuit, and in an orthogonal projection to a main surface of the first substrate including the display region, the first circuit is arranged inside the outer edge of the display region, and a center of the display region is arranged inside an outer edge of the first circuit, is provided.

According to some other embodiments, a light emitting device in which a first substrate including a display region where a plurality of pixels are arranged and a second substrate including circuits configured to operate the plurality of pixels are stacked, wherein the circuits include a first circuit and a second circuit located between the first circuit and an outer edge of the second substrate, the first circuit has a larger heat generation amount per unit area than the second circuit, the plurality of pixels are supplied with power by a plurality of electrode patterns and an electrode layer arranged to cover each of the plurality of pixels and configured to transmit light emitted by each of the plurality of pixels, and in an orthogonal projection to a main surface of the first substrate including the display region, the electrode layer is connected to a first power supply pattern arranged outside the display region, and the plurality of electrode patterns are connected to a second power supply pattern arranged outside the display region, a region surrounding the display region includes a first region and a second region, at least one of a connection portion between the electrode layer and the first power supply pattern and a connection portion between the plurality of electrode patterns and the second power supply pattern is arranged in the first region and not arranged in the second region, and a virtual line extending from a center of the display region toward a center of the first circuit does not intersect the first region, is provided.

Further features of the present invention will become apparent from the following description of exemplary embodiments (with reference to the attached drawings).

### BRIEF DESCRIPTION OF THE DRAWINGS

FIG. 1 is a view showing an example of the arrangement of a light emitting device according to an embodiment;

FIG. 2 is a sectional view showing an example of the arrangement of the light emitting device shown in FIG. 1;

FIG. 3 is a circuit diagram showing an example of the arrangement of the pixel of the light emitting device shown in FIG. 1;

FIG. 4 is a view showing an example of the arrangement of the signal processing circuit of the light emitting device shown in FIG. 1;

FIG. 5 is a view showing a modification of the light emitting device shown in FIG. 1;

FIG. 6 is a view showing an example of the arrangement of the signal processing circuit of the light emitting device shown in FIG. 5;

FIG. 7 is a view showing a modification of the light emitting device shown in FIG. 1;

FIG. 8 is a view showing an example of the arrangement of the signal processing circuit of the light emitting device shown in FIG. 7;

FIGS. 9A and 9B are sectional views showing an example of the arrangement of the pixel of the light emitting device shown in FIG. 1;

FIGS. 10A to 10C are views showing an example of an image forming device using the light emitting device according to the embodiment;

FIG. 11 is a view showing an example of a display device using the light emitting device according to the embodiment;

FIG. 12 is a view showing an example of a photoelectric conversion device using the light emitting device according to the embodiment;

FIG. 13 is a view showing an example of an electronic apparatus using the light emitting device according to the embodiment;

FIGS. 14A and 14B are views each showing an example of a display device using the light emitting device according to the embodiment;

FIG. 15 is a view showing an example of an illumination device using the light emitting device according to the embodiment;

FIG. 16 is a view showing an example of a moving body using the light emitting device according to the embodiment; and

FIGS. 17A and 17B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

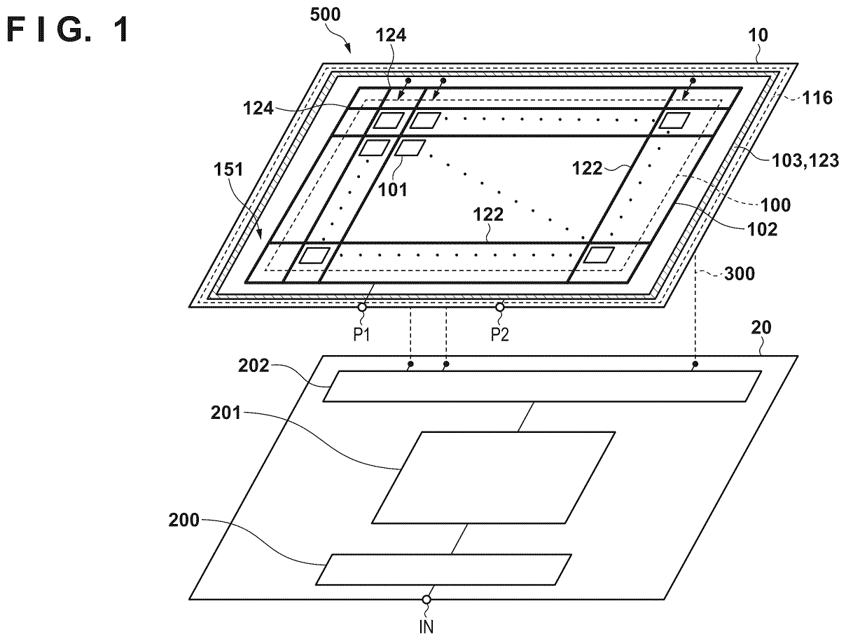

With reference to FIGS. 1 to 8, a light emitting device according to an embodiment of the present disclosure will be described. FIG. 1 schematically shows the arrangement of a light emitting device 500 according to the embodiment. In the light emitting device 500, a substrate 10 including a display region 100 where a plurality of pixels 101 are arranged and a substrate 20 including circuits configured to operate the plurality of pixels 101 are stacked. The plurality of pixels 101 arranged in the display region 100 of the substrate 10 may be arrayed to form a plurality of rows and a plurality of columns.

The plurality of pixels 101 are supplied with power by a plurality of electrode patterns 122 and an electrode layer 116 arranged to cover each of the plurality of pixels and configured to transmit light emitted by each of the plurality of pixels. In the arrangement shown in FIG. 1, the plurality of electrode patterns 122 include the electrode patterns 122 extending along a row direction (for example, a horizontal direction in FIG. 1) and the electrode patterns 122 extending along a column direction intersecting the row direction. However, the plurality of electrode patterns 122 may extend along only one of the row direction and the column direction in the display region 100.

In an orthogonal projection to a main surface 151 of the substrate 10 including the display region 100, the electrode layer 116 is connected to a power supply pattern 103 arranged outside the display region 100. The electrode layer 116 is electrically connected to an external electrode P2 via the power supply pattern 103. Each of the plurality of pixels 101 is supplied with a power supply voltage from the external electrode P2 via the electrode layer 116 and the power supply pattern 103. The power supply pattern 103 may be arranged to surround the outer edge of the display region 100 as shown in FIG. 1.

In the orthogonal projection to the main surface 151 of the substrate 10, the plurality of electrode patterns 122 are connected to a power supply pattern 102 arranged outside the display region 100. The plurality of electrode patterns 122 are electrically connected to an external electrode P1 via the power supply pattern 102. Each of the plurality of pixels 101 is supplied with a power supply voltage from the external electrode P1 via the plurality of electrode patterns 122 and the power supply pattern 102. The power supply pattern 102 may be arranged to surround the outer edge of the display region 100 as shown in FIG. 1.

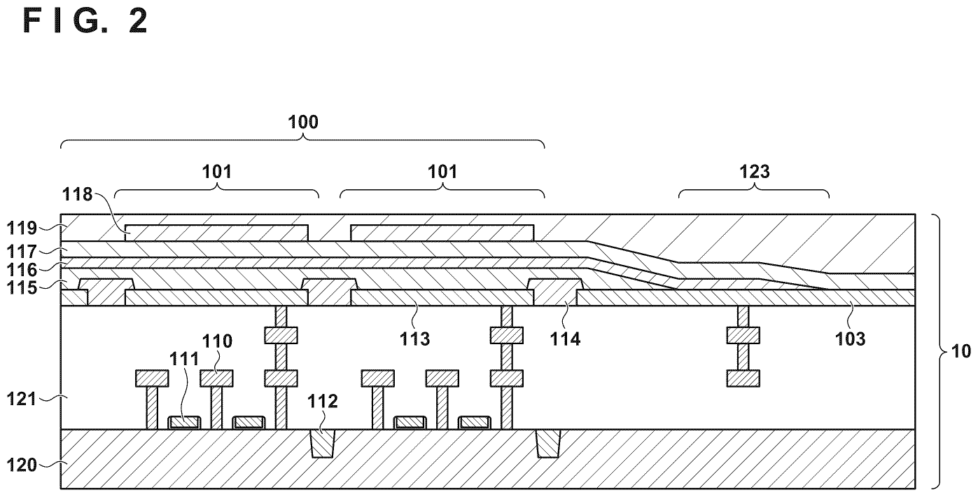

FIG. 2 is a sectional view showing an example of the arrangement of the substrate 10. In the arrangement shown in FIG. 2, the substrate 10 can include a semiconductor substrate 120, an interlayer insulating film 121, wiring patterns 110, transistors 111, Shallow Trench Isolations (STIs) 112, lower electrodes 113, banks 114, a light emitting layer 115, the electrode layer 116, a sealing film 117, color filters 118, and a protection film 119.

A plurality of transistors 111 element-isolated by the STIs 112 are arranged in the semiconductor substrate 120 using silicon or the like. The interlayer insulating film 121 in which the wiring patterns 110 are formed is arranged on the semiconductor substrate 120, and the lower electrodes 113 are arranged on the interlayer insulating film 121. The lower electrode 113 can be arranged in correspondence with each of the plurality of pixels 101. Each lower electrode 113 is electrically isolated by the banks 114 using a dielectric material. The light emitting layer 115 using organic electroluminescence (EL) or the like is arranged between the lower electrodes 113 and the electrode layer 116, and light is emitted according to a current flowing between the lower electrode 113 and the electrode layer 116 via the light emitting layer 115.

Some of the wiring patterns 110 formed in the display region 100 function as the plurality of electrode patterns 122 described above. Outside the display region 100, the electrode layer 116 is in contact with the power supply pattern 103 formed in the same conductor layer as the lower electrodes 113. Here, in the arrangement shown in FIG. 2, the power supply pattern 103 is formed in the same conductor layer as the lower electrodes 113, but the present invention is not limited thereto. The power supply pattern 103 may be formed using a suitable conductive layer. As shown in FIG. 1, a connection portion 123 connecting the electrode layer 116 and the power supply pattern 103 may be arranged to surround the display region 100. The electrode layer 116 can be electrically connected to the lower electrode 113 formed in correspondence with each pixel 101 via the light emitting layer 115. The lower electrode 113 is connected to the electrode pattern 122 via the transistor 111 or the like.

The sealing film 117 can be provided to protect the light emitting layer 115, the transistors 111, and the like against moisture and the like. An inorganic material such as silicon nitride or aluminum oxide may be used for the sealing film 117. Alternatively, an organic material such as a resin may be used as the sealing film 117. The color filters 118 may respectively transmit different colors such as red, blue, and green for each pixel 101. With this, the light emitting device 500 can implement color display. The color filters 118 may not be arranged. In this case, the light emitting device 500 may be a monochrome display device, or may be a color display device in which the light emitting layer 115 emits light components of different colors for each pixel 101. The protection film 119 can be provided to protect the substrate 10 against dust and the like. For the protection film 119, an inorganic or organic material may be used.

In the substrate 20, circuits configured to operate the plurality of pixels 101 arranged in the display region 100 of the substrate 10 are arranged. In the arrangement shown in FIG. 1, the circuits configured to operate the plurality of pixels 101 arranged in the display region 100 of the substrate 10 include an input processing circuit 200, a signal processing circuit 201, and a driving circuit 202. In the arrangement shown in FIG. 1, each of the input processing circuit 200 and the driving circuit 202 is located between the signal processing circuit 201 and the outer edge of the substrate 20. The input processing circuit 200 converts an analog video signal supplied from an input terminal IN into a digital video signal. The signal processing circuit 201 is a digital circuit that generates, based on the digital video signal generated by the input processing circuit 200, a digital signal for controlling light emission of the plurality of pixels 101. The signal processing circuit 201 may have correction functions for gamma correction, white balance correction, and the like. Based on the digital signal generated by the signal processing circuit 201, the driving circuit 202 generates a driving signal for driving the plurality of pixels 101. The generated driving signal is supplied to each of the plurality of pixels 101 arranged on the substrate 10 via a plurality of electric connection portions 300.

The signal processing circuit 201 is an example of the circuit with the larger heat generation amount per unit area than the input processing circuit 200 and the driving circuit 202. For example, the signal processing circuit 201 may be a circuit with the largest heat generation amount per unit area among the circuits configured to operate the pixels 101 and arranged in the substrate 20. Alternatively, for example, the signal processing circuit 201 may be a circuit constituting at least a part of a digital circuit that generates, based on a signal input from the outside, a digital signal, such as the above-described digital video signal, for controlling the plurality of pixels 101. For example, the signal processing circuit 201 may be a circuit with the higher power consumption per unit area than the input processing circuit 200 and the driving circuit 202, or may be a circuit with the highest power consumption per unit area among the circuits configured to operate the pixels 101 and arranged in the substrate 20. Alternatively, for example, the signal processing circuit 201 may be a circuit with the higher arrangement density of the transistors 111 than the input processing circuit 200 and the driving circuit 202, or may be a circuit with the highest arrangement density of the transistors 111 among the circuits configured to operate the pixels 101 and arranged in the substrate 20.

In addition to the input processing circuit 200, the signal processing circuit 201, and the driving circuit 202, for example, a temperature measurement circuit that acquires the temperature of the light emitting device 500 may be arranged in the substrate 20. In addition, for example, a circuit having another function, such as an OTP-ROM for storing correction data, may be arranged in the substrate 20. In this case, the signal processing circuit 201 can be a circuit with the largest heat generation amount per unit area among all circuits arranged in the substrate 20. Alternatively, the signal processing circuit 201 may be a circuit with the highest power consumption per unit area or the highest arrangement density of the transistors 111 among all circuits arranged in the substrate 20.

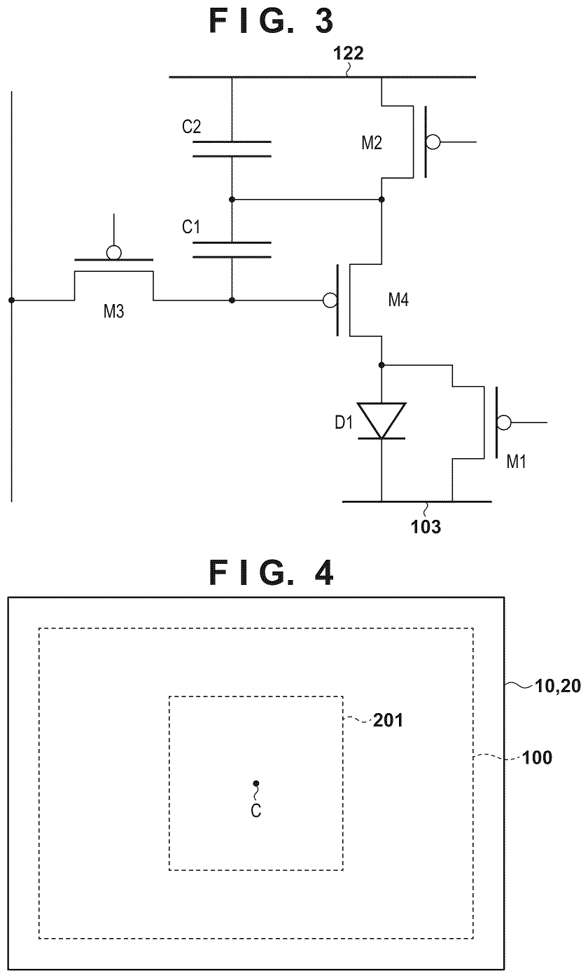

FIG. 3 is a view showing an example of the arrangement of the pixel 101 arranged in the display region 100. In the arrangement shown in FIG. 3, the pixel 101 includes a light emitting element D1, a reset transistor M1, capacitive elements C1 and C2, a switching transistor M2, a row selection transistor M3, and a driving transistor M4. If the difference between the power supply voltage supplied from the electrode pattern 122 and the power supply voltage supplied from the electrode layer 116 decreases, the voltage applied to the driving transistor M4 and the light emitting element D1 decreases, so that the light emission intensity of the pixel 101 decreases. If the temperature increases, the drain current of the driving transistor M4 increases and the current for driving the light emitting element D1 increases, so that the light emission intensity of the pixel 101 increases. In this manner, the light emission intensity of the pixel 101 arranged in the display region 100 depends on both the temperature and the supplied power supply voltage.

FIG. 4 shows an example of the arrangement of the signal processing circuit 201 in the orthogonal projection to the main surface 151 of the substrate 10. As shown in FIG. 4, in this embodiment, the signal processing circuit 201 is arranged inside the outer edge of the display region 100. A center C of the display region 100 is arranged inside the outer edge of the signal processing circuit 201. The center C of the display region 100 can be, for example, the geometric centroid position of the display region 100 in the orthogonal projection to the main surface 151 of the substrate 10. With this arrangement, the temperature of the plurality of pixels 101 caused by the heat generation of the signal processing circuit 201 tends to increase from the outer edge of the display region 100 toward the center C. As a result, the light emission intensity distribution of the display region 100 caused by the temperature distribution tends to increase from the outer edge of the display region 100 toward the center C.

On the other hand, the electrode layer 116 is supplied with power (voltage) from the power supply pattern 103 (connection portion 123) arranged to surround the display region 100. Further, a connection portion 124 between the power supply pattern 102 and the electrode patterns 122 extending along the row direction and the column direction is arranged to surround the display region 100. That is, the power (power supply voltage) supplied from each of the external electrode P1 and the external electrode P2 is supplied from the vicinity of the outer edge of the display region 100. Therefore, the difference between the power supply voltage supplied to the pixel 101 from the external electrode P1 and the power supply voltage supplied to the pixel 101 from the external electrode P2, which is caused by a voltage drop, tends to decrease from the outer edge of the display region 100 toward the center C. As a result, the light emission intensity distribution of the display region 100 caused by the power supply voltage distribution tends to decrease from the outer edge of the display region 100 toward the center C.

In the light emitting device 500 having the above-described arrangement, the light emission intensity distribution caused by the temperature distribution according to the heat generation of the signal processing circuit 201 and the light emission intensity distribution caused by the distribution of power supply voltage supplied to the plurality of pixels 101 have opposite distributions, so that they reduce each other. That is, the light emitting device 500 according to this embodiment can effectively suppress the non-uniform light emission intensity distribution caused by the non-uniform temperature distribution in the display region 100 and the non-uniform light emission intensity distribution caused by the voltage drop of the power supply voltage in the display region.

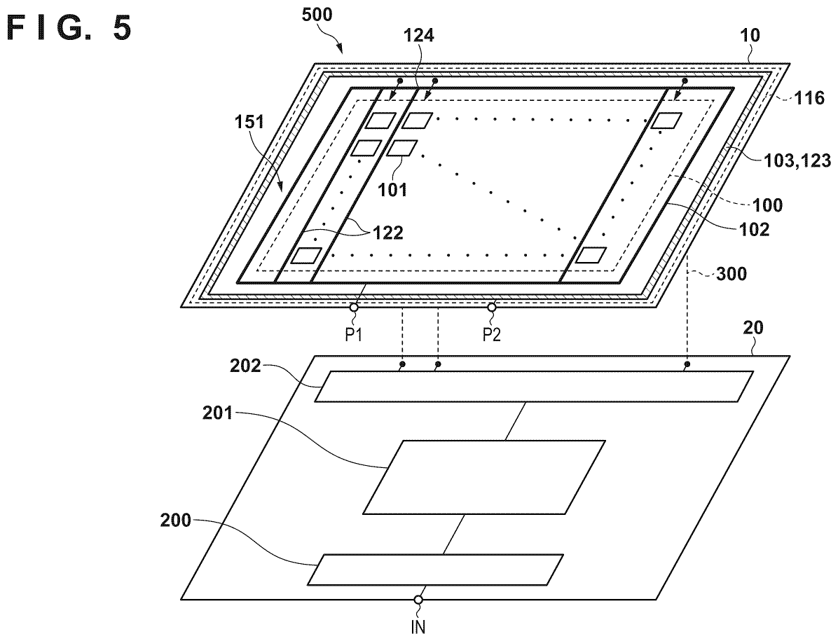

FIG. 5 shows a modification of the light emitting device 500 shown in FIG. 1. Differences from the above-described arrangement will be mainly described below, and the arrangement that may be similar to the above-described arrangement will not be described, as appropriate.

In the arrangement shown in FIG. 1, the plurality of electrode patterns 122 are arranged in the row direction and the column direction to form a grid pattern. On the other hand, in the arrangement shown in FIG. 5, each of the plurality of electrode patterns 122 extends along the column direction, and is connected (connection portion 124) to a portion of the power supply pattern 102 which extends along the row direction intersecting the column direction. Further, each of the plurality of electrode patterns 122 is connected to two sides of the power supply pattern 102 which extend along the row direction. With the arrangement of the electrode patterns 122 shown in FIG. 5, the gradient of the power supply voltage supplied to each of the plurality of pixels 101 from the external electrode P1 via the electrode pattern 122 tends to be steeper in the column direction than in the row direction.

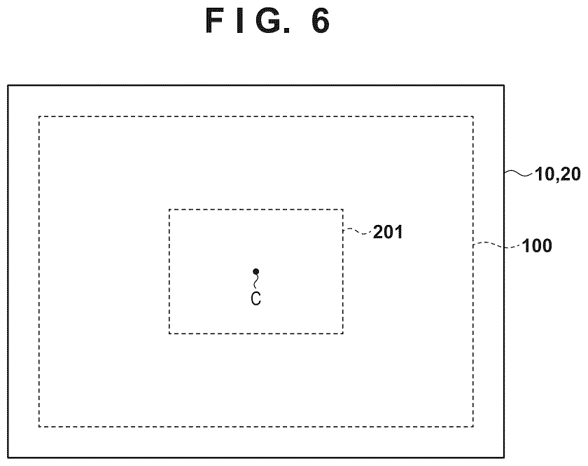

FIG. 6 shows an example of the arrangement of the signal processing circuit 201 in the orthogonal projection to the main surface 151 of the substrate 10. As shown in FIG. 6, in accordance with the arrangement of the plurality of electrode patterns 122, the length of the signal processing circuit 201 along the row direction intersecting the extending direction of the electrode pattern 122 is larger than the length thereof along the column direction in which the electrode pattern 122 extends. Considering the steep gradient of the power supply voltage in the column direction described above, a lower power supply voltage can be supplied to the pixel 101 arranged at a position away from the center C of the display region 100 in the row direction than the pixel 101 arranged at a position away from the center C in the column direction. Hence, the signal processing circuit 201 is arranged to overlap the pixels 101 that are considered to be supplied with the lower power supply voltage from the external electrode P1. That is, the gradient of the temperature of the plurality of pixels 101 caused by the heat generation of the signal processing circuit 201 tends to be steeper in the column direction than in the row direction.

Even when the electrode patterns 122 are arranged along one direction, the signal processing circuit 201 is arranged as shown in FIG. 6. With this arrangement, the light emission intensity distribution caused by the temperature distribution according to the heat generation of the signal processing circuit 201 and the light emission intensity distribution caused by the distribution of power supply voltage supplied to the plurality of pixels 101 have opposite distributions, so that they reduce each other. That is, the light emitting device 500 according to this embodiment can effectively suppress the non-uniform light emission intensity distribution caused by the non-uniform temperature distribution in the display region 100 and the non-uniform light emission intensity distribution caused by the voltage drop of the power supply voltage in the display region.

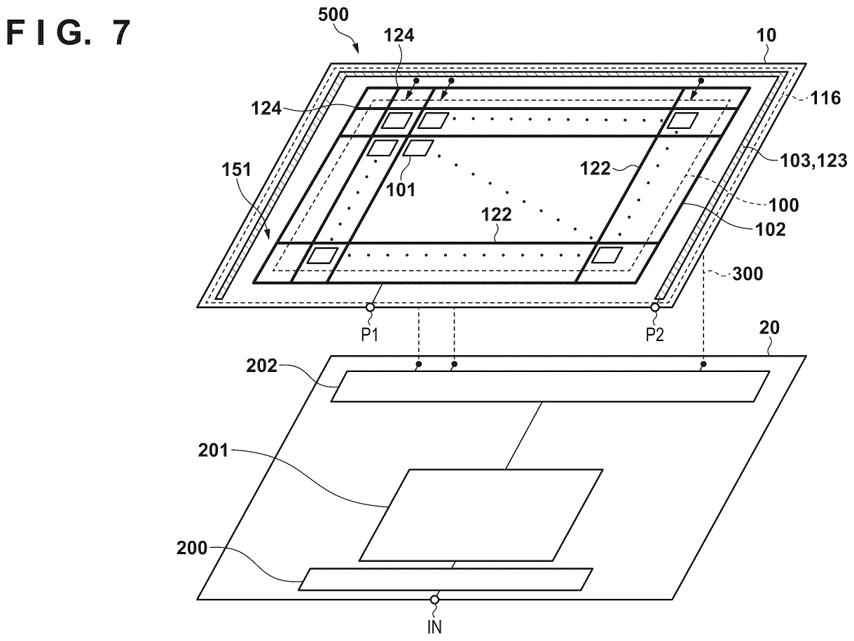

FIG. 7 shows a modification of the light emitting device 500 shown in FIG. 1. Differences from the above-described arrangement will be mainly described below, and the arrangement that may be similar to the above-described arrangement will not be described, as appropriate.

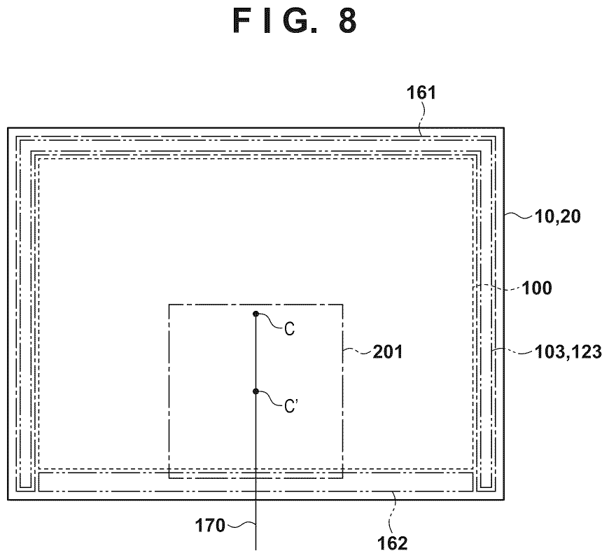

In the arrangement shown in FIG. 1, the connection portion 123 between the electrode layer 116 and the power supply pattern 103 is arranged to surround the display region 100. On the other hand, in the arrangement shown in FIG. 7, the connection portion 123 between the electrode layer 116 and the power supply pattern 103 is arranged in a part of the outer periphery of the display region 100. Here, as shown in FIG. 8, of the region surrounding the display region 100, a region where the connection portion 123 between the electrode layer 116 and the power supply pattern 103 is arranged is referred to as a region 161, and a region where the connection portion 123 is not arranged is referred to as a region 162. The power supply voltage supplied to the plurality of pixels 101 from the external electrode P2 via the electrode layer 116 due to a voltage drop is higher at a position closer to the connection portion 123 (region 161) and lower at a position farther from the connection portion 123 (region 161).

FIG. 8 shows an example of the arrangement of the signal processing circuit 201 in the orthogonal projection to the main surface 151 of the substrate 10. If the connection portion 123 between the electrode layer 116 and the power supply pattern 103 has the arrangement as shown in FIG. 7, the signal processing circuit 201 is arranged such that a virtual line 170 extending from the center C of the display region 100 toward a center C′ of the signal processing circuit 201 does not intersect the region 161. Further, the signal processing circuit 201 is arranged such that the virtual line 170 extending from the center C of the display region 100 toward the center C′ of the signal processing circuit 201 intersects the region 162. With this arrangement, the signal processing circuit 201 is arranged at a position relatively away from the connection portion 123 between the electrode layer 116 and the power supply pattern 103. That is, the signal processing circuit 201 is arranged to overlap the pixels 101 that are considered to be supplied with the lower power supply voltage from the external electrode P1. Here, the center C′ of the signal processing circuit 201 can be, for example, the geometric centroid position of the signal processing circuit 201 in the orthogonal projection to the main surface 151 of the substrate 10.

In this manner, even when the connection portion 123 between the electrode layer 116 and the power supply pattern 103 is arranged only in a part of the region surrounding the display region, the signal processing circuit 201 is arranged as shown in FIG. 8. With this arrangement, the light emission intensity distribution caused by the temperature distribution according to the heat generation of the signal processing circuit 201 and the light emission intensity distribution caused by the distribution of power supply voltage supplied to the plurality of pixels 101 have opposite distributions, so that they reduce each other. That is, the light emitting device 500 according to this embodiment can effectively suppress the non-uniform light emission intensity distribution caused by the non-uniform temperature distribution in the display region 100 and the non-uniform light emission intensity distribution caused by the voltage drop of the power supply voltage in the display region.

In the arrangement shown in FIGS. 7 and 8, a part of the signal processing circuit 201 may be arranged outside the outer edge of the display region 100 as shown in FIG. 8. In this case, in the orthogonal projection to the main surface 151 of the substrate 10, for example, the center C′ of the signal processing circuit 201 may be arranged inside the outer edge of the display region 100, or the center C′ of the signal processing circuit 201 may be arranged outside the outer edge of the display region 100. Also in the arrangement shown in FIGS. 7 and 8, the signal processing circuit 201 may be arranged inside the outer edge of the display region 100 as shown in FIG. 4 or 6. The signal processing circuit 201 may be arranged at a suitable position in accordance with the relationship between the non-uniform light emission intensity distribution caused by the non-uniform temperature distribution in the display region 100 and the non-uniform light emission intensity distribution caused by the voltage drop of the power supply voltage in the display region.

A case has been described in which, in the arrangement shown in FIGS. 7 and 8, the connection portion 123 between the electrode layer 116 and the power supply pattern 103 is arranged only in a part of the region surrounding the display region. However, the present invention is not limited to this. For example, also in a case where the connection portion 124 between the plurality of electrode patterns 122 and the power supply pattern 102 is arranged in the region 161 but not in the region 162, the signal processing circuit 201 may be arranged at the position described using FIG. 8. With this arrangement, the light emitting device 500 can effectively suppress the non-uniform light emission intensity distribution caused by the non-uniform temperature distribution in the display region 100 and the non-uniform light emission intensity distribution caused by the voltage drop of the power supply voltage in the display region.

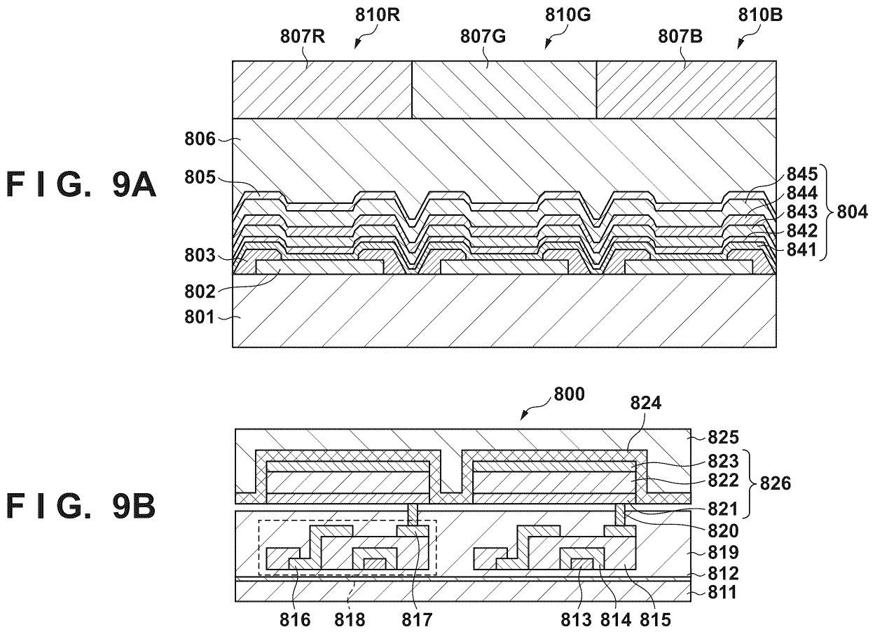

Here, application examples in which the light emitting device 500 according to this embodiment is applied to an image forming device, a display device, a photoelectric conversion device, an electronic apparatus, an illumination device, a moving body, and a wearable device will be described with reference to FIGS. 9A to 17B. The description will be given assuming that, for example, an organic light emitting element such as an organic EL element using an organic light emitting material is arranged in the pixel 101 of the light emitting device 500. Details of each component arranged in the pixel 101 of the light emitting device 500 described above will be described first, and the application examples will be described after that.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in an arrangement including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this arrangement, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 9A shows an example of the pixel 101 arranged in the light emitting device 500. The pixel includes sub-pixels 810 (pixels 101). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display device 800 (corresponding to the above-described light emitting device 500) shown in FIG. 9B is provided with an organic light emitting element 826 and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 9B. That is, one of the anode and cathode and one of the source electrode and drain electrode of the TFT are electrically connected. The TFT indicates a thin-film transistor.

In the display device 800 shown in FIG. 9B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 9B but may be used as another switching element.

The transistor used in the display device 800 shown in FIG. 9B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 9B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

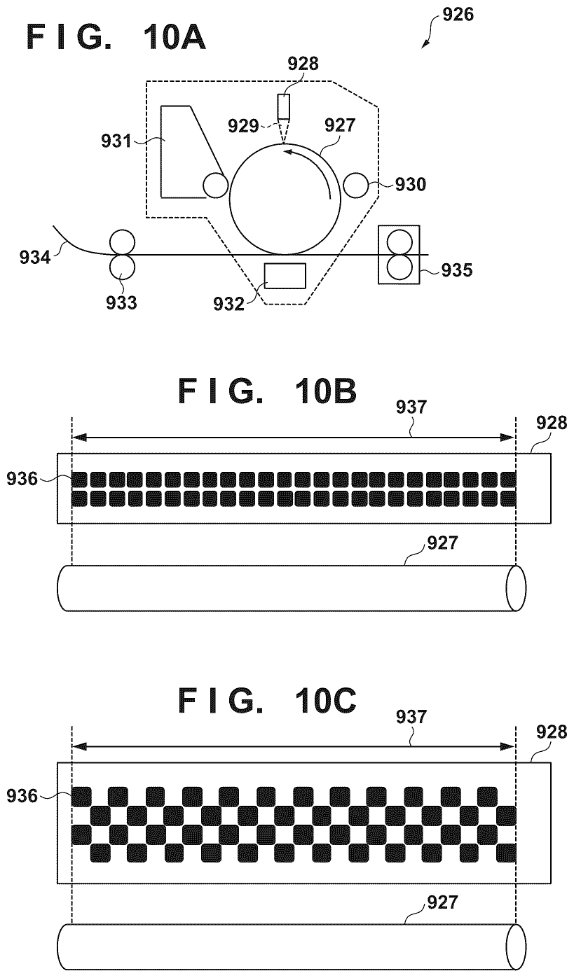

FIGS. 10A to 10C are schematic views showing an example of an image forming device using the light emitting device 500 according to this embodiment. An image forming device 926 shown in FIG. 10A includes a photosensitive member 927, an exposure light source 928, a developing unit 931, a charging unit 930, a transfer device 932, a conveyance unit 933 (a conveyance roller in the arrangement shown in FIG. 10A), and a fixing device 935.

Light 929 is emitted from the exposure light source 928, and an electrostatic latent image is formed on the surface of the photosensitive member 927. The light emitting device 500 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 10B and 10C is a schematic view showing a form in which a plurality of light emitting units 936 are arranged in the exposure light source 928 along the longitudinal direction of a long substrate. The light emitting device 500 can be applied to each of the light emitting units 936. That is, a plurality of the pixels 101 are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 10B shows a form in which the light emitting units 936 are arranged along the long-axis direction of the photosensitive member 927. FIG. 10C shows a form, which is a modification of the arrangement of the light emitting units 936 shown in FIG. 10B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 10C can be referred to as, for example, an arrangement in a grid pattern, an arrangement in a staggered pattern, or an arrangement in a checkered pattern.

FIG. 11 is a schematic view showing an example of the display device using the light emitting device 500 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 500 can be applied to the display panel 1005. The pixels 101 arranged in the light emitting device 500 functioning as the display panel 1005 operate in a state in which they are connected to the active elements such as transistors arranged on the circuit board 1007.

The display device 1000 shown in FIG. 11 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

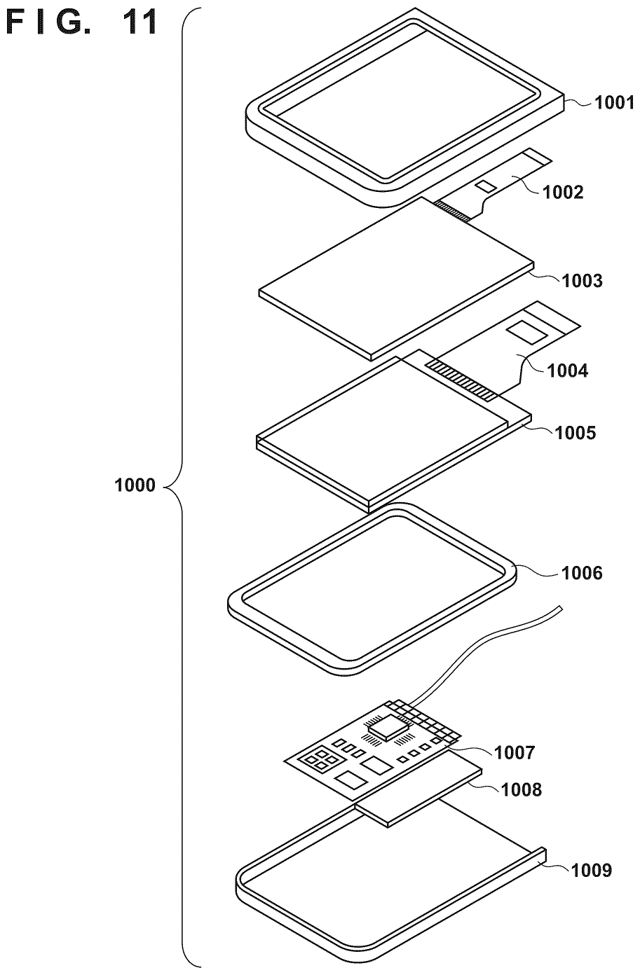

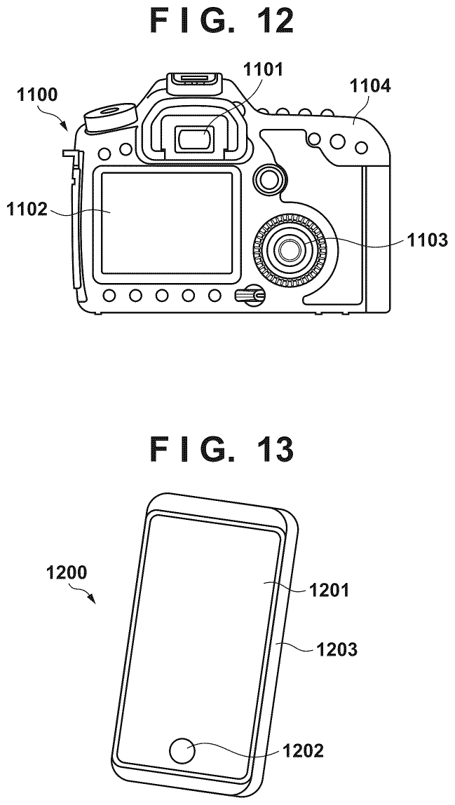

FIG. 12 is a schematic view showing an example of the photoelectric conversion device using the light emitting device 500 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 500 according to this embodiment can be applied to the viewfinder 1101 or the rear display 1102 as a display unit. In this case, the light emitting device 500 can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device 500 in which the pixel 101 including the light emitting element using the organic light emitting material such as an organic EL element is arranged may be used for the viewfinder 1101 or the rear display 1102. This is so because the organic light emitting material has a high response speed. The light emitting device 500 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 500 may be applied to a display unit of an electronic apparatus. At this time, the display unit can have both a display function and an operation function. Examples of the portable terminal are a portable phone such as a smartphone, a tablet, and a head mounted display.

FIG. 13 is a schematic view showing an example of an electronic apparatus using the light emitting device 500 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 500 according to this embodiment can be applied to the display unit 1201.

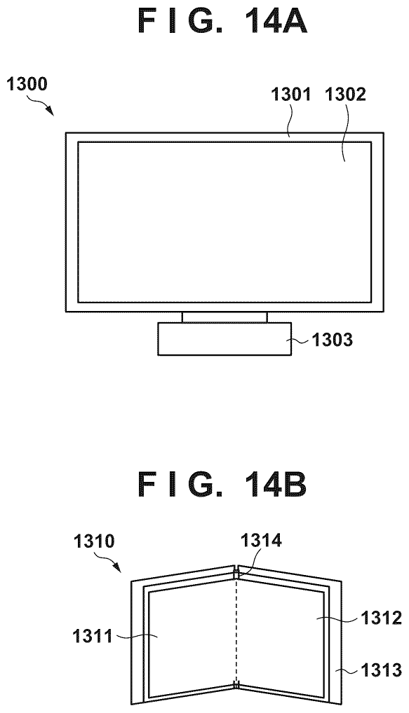

FIGS. 14A and 14B are schematic views showing examples of the display device using the light emitting device 500 according to this embodiment. FIG. 14A shows a display device such as a television monitor or a PC monitor. A display device 1300 includes a frame 1301 and a display unit 1302. The light emitting device 500 according to this embodiment can be applied to the display unit 1302. The display device 1300 can include a base 1303 that supports the frame 1301 and the display unit 1302. The base 1303 is not limited to the form shown in FIG. 14A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 14B is a schematic view showing another example of the display device using the light emitting device 500 according to this embodiment. A display device 1310 shown in FIG. 14B can be folded, and is a so-called foldable display device. The display device 1310 includes a first display unit 1311, a second display unit 1312, a housing 1313, and a bending point 1314. The light emitting device 500 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

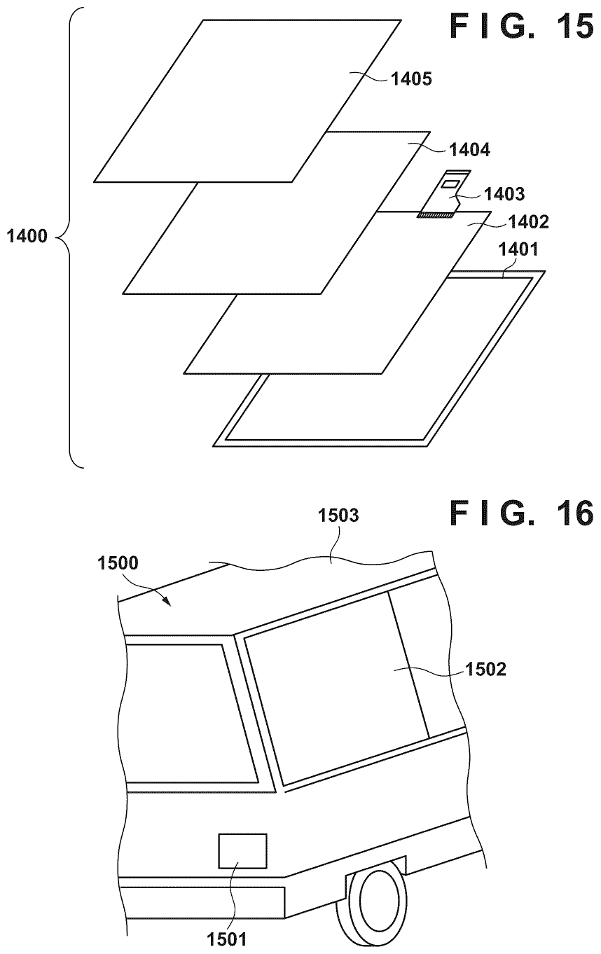

FIG. 15 is a schematic view showing an example of the illumination device using the light emitting device 500 according to this embodiment. An illumination device 1400 can include a housing 1401, a light source 1402, a circuit board 1403, an optical film 1404, and a light diffusing unit 1405. The light emitting device 500 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 500 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 16 is a schematic view of an automobile having a taillight as an example of a vehicle lighting appliance using the light emitting device 500 according to this embodiment. An automobile 1500 has a taillight 1501, and can have a form in which the taillight 1501 is turned on when performing a braking operation or the like. The light emitting device 500 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 500 according to this embodiment can be applied to the taillight 1501. The taillight 1501 can include a protection member for protecting the light emitting device 500 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 500 according to this embodiment may be used. In this case, the constituent materials of the electrodes and the like of the light emitting device 500 are formed by transparent members.

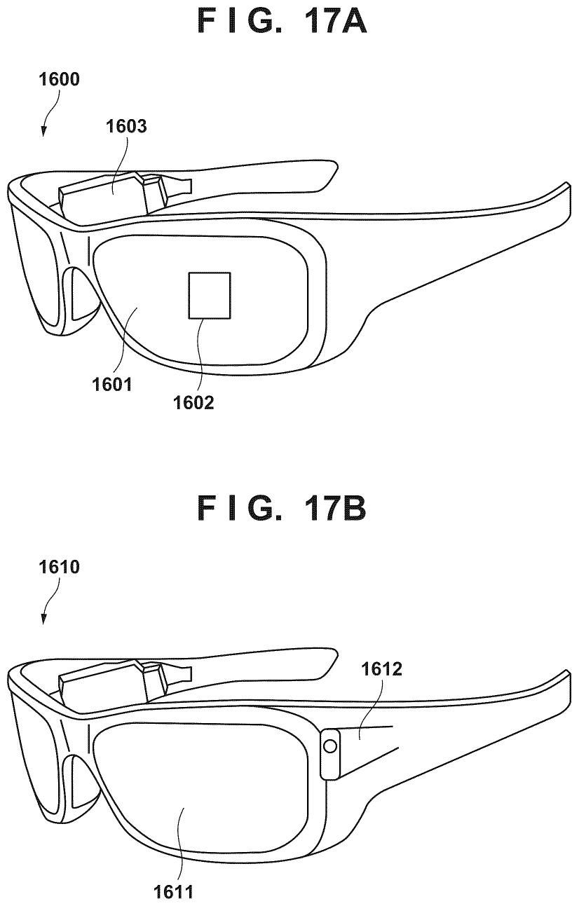

Further application examples of the light emitting device 500 according to this embodiment will be described with reference to FIGS. 17A and 17B. The light emitting device 500 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 17A. An image capturing device 1602 such as a CMOS sensor or an SPAD is provided on the surface side of a lens 1601 of the glasses 1600. In addition, the light emitting device 500 according to this embodiment is provided on the back surface side of the lens 1601.

The glasses 1600 further include a control device 1603. The control device 1603 functions as a power supply that supplies electric power to the image capturing device 1602 and the light emitting device 500 according to each embodiment. In addition, the control device 1603 controls the operations of the image capturing device 1602 and the light emitting device 500. An optical system configured to condense light to the image capturing device 1602 is formed on the lens 1601.

Glasses 1610 (smartglasses) according to one application example will be described with reference to FIG. 17B. The glasses 1610 include a control device 1612, and an image capturing device corresponding to the image capturing device 1602 and the light emitting device 500 are mounted on the control device 1612. The image capturing device in the control device 1612 and an optical system configured to project light emitted from the light emitting device 500 are formed in a lens 1611, and an image is projected to the lens 1611. The control device 1612 functions as a power supply that supplies electric power to the image capturing device and the light emitting device 500, and controls the operations of the image capturing device and the light emitting device 500. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 500 according to the embodiment of the present disclosure can include an image capturing device including a light receiving element, and control a displayed image based on the line-of-sight information of the user from the image capturing device.

More specifically, the light emitting device 500 decides a first visual field region at which the user is gazing and a second visual field region other than the first visual field region based on the line-of-sight information. The first visual field region and the second visual field region may be decided by the control device of the light emitting device 500, or those decided by an external control device may be received. In the display region of the light emitting device 500, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 500, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 500, the image capturing device, or an external device. If the external device holds the AI program, it is transmitted to the light emitting device 500 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-013307, filed Jan. 31, 2024, which is hereby incorporated by reference herein in its entirety.

What is claimed is:

1. A light emitting device in which a first substrate including a display region where a plurality of pixels are arranged and a second substrate including circuits configured to operate the plurality of pixels are stacked, wherein
the circuits include a first circuit and a second circuit located between the first circuit and an outer edge of the second substrate,
the first circuit has a larger heat generation amount per unit area than the second circuit, and
in an orthogonal projection to a main surface of the first substrate including the display region,
the first circuit is arranged inside the outer edge of the display region, and
a center of the display region is arranged inside an outer edge of the first circuit.

2. The device according to claim 1, wherein
the plurality of pixels are supplied with power by a plurality of electrode patterns and an electrode layer arranged to cover each of the plurality of pixels and configured to transmit light emitted by each of the plurality of pixels, and
in the orthogonal projection to the main surface, the electrode layer is connected to a first power supply pattern arranged outside the display region, and the plurality of electrode patterns are connected to a second power supply pattern arranged outside the display region.

3. The device according to claim 2, wherein
each of the first power supply pattern and the second power supply pattern is arranged to surround the display region, and
a connection portion between the electrode layer and the first power supply pattern is arranged to surround the display region.

4. The device according to claim 3, wherein
the plurality of electrode patterns include an electrode pattern extending along a first direction and an electrode pattern extending along a second direction intersecting the first direction, and
a connection portion between the plurality of electrode patterns and the second power supply pattern is arranged to surround the display region.

5. The device according to claim 3, wherein
each of the plurality of electrode patterns extends along a first direction, and is connected to a portion of the second power supply pattern which extends along a second direction intersecting the first direction.

6. The device according to claim 5, wherein
each of the plurality of electrode patterns is connected to a first side and a second side of the second power supply pattern which extend along the second direction.

7. The device according to claim 5, wherein
a length of the first circuit along the second direction is larger than a length thereof along the first direction.

8. The device according to claim 2, wherein
a region surrounding the display region includes a first region and a second region,
at least one of a connection portion between the electrode layer and the first power supply pattern and a connection portion between the plurality of electrode patterns and the second power supply pattern is arranged in the first region and not arranged in the second region, and
in the orthogonal projection to the main surface, a virtual line extending from a center of the display region toward a center of the first circuit does not intersect the first region.

9. The device according to claim 8, wherein
the virtual line intersects the second region.

10. The device according to claim 1, wherein
the first circuit constitutes at least a part of a digital circuit configured to generate, based on a signal input from an outside, a digital signal for controlling the plurality of pixels.

11. The device according to claim 1, wherein
the first circuit is a circuit with the largest heat generation amount per unit area among the circuits.

12. The device according to claim 1, wherein
the first circuit is a circuit with the largest heat generation amount per unit area among circuits arranged in the second substrate.

13. A light emitting device in which a first substrate including a display region where a plurality of pixels are arranged and a second substrate including circuits configured to operate the plurality of pixels are stacked, wherein
the circuits include a first circuit and a second circuit located between the first circuit and an outer edge of the second substrate,
the first circuit has a larger heat generation amount per unit area than the second circuit,
the plurality of pixels are supplied with power by a plurality of electrode patterns and an electrode layer arranged to cover each of the plurality of pixels and configured to transmit light emitted by each of the plurality of pixels, and
in an orthogonal projection to a main surface of the first substrate including the display region,
the electrode layer is connected to a first power supply pattern arranged outside the display region, and the plurality of electrode patterns are connected to a second power supply pattern arranged outside the display region,
a region surrounding the display region includes a first region and a second region,
at least one of a connection portion between the electrode layer and the first power supply pattern and a connection portion between the plurality of electrode patterns and the second power supply pattern is arranged in the first region and not arranged in the second region, and
a virtual line extending from a center of the display region toward a center of the first circuit does not intersect the first region.

14. The device according to claim 13, wherein
the first circuit constitutes at least a part of a digital circuit configured to generate, based on a signal input from an outside, a digital signal for controlling the plurality of pixels.

15. A display device comprising the light emitting device according to claim 1, and an active element connected to the light emitting device.

16. A photoelectric conversion device comprising an optical unit including a plurality of lenses, an image sensor configured to receive light having passed through the optical unit, and a display unit configured to display an image,
wherein the display unit displays an image captured by the image sensor, and includes the light emitting device according to claim 1.

17. An electronic apparatus comprising a housing provided with a display unit, and a communication unit provided in the housing and configured to perform external communication,
wherein the display unit includes the light emitting device according to claim 1.

18. An illumination device comprising a light source, and at least one of a light diffusing unit and an optical film,
wherein the light source includes the light emitting device according to claim 1.

19. A moving body comprising a main body, and a lighting appliance provided in the main body,
wherein the lighting appliance includes the light emitting device according to claim 1.

20. A wearable device comprising a display device configured to display an image,
wherein the display device includes the light emitting device according to claim 1.
